(19) United States
(12) Patent Application Publication
(10) Pub. No.: US 2008/0042235 A1
(43) Pub. Date: Feb. 21, 2008

(54) Semiconductor memory device

(75) Inventor: Noriaki Kodama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/889,597

(22) Filed: Aug. 15, 2007

(30) Foreign Application Priority Data
Aug. 16, 2006 (JP) 221983/ 2006

(51) Int. Cl. H01L 29/00

(52) U.S. Cl. 257/530; 257/E29.001

(57) ABSTRACT

A semiconductor memory device for reliably inducing a breakdown in the dielectric when utilizing an antifuse to write on the dielectric film even when the process scale has become more detailed. The semiconductor memory device includes an antifuse serving as the memory node, and a current regulator connected in serial with the antifuse. The current controller is comprised of a P-type semiconductor substrate and a reverse-conduction N-type well, a diode coupled to a P+ diffusion substrate of the same conducing type as the P-type semiconductor substrate. The antifuse contains at least a structure where an electrode is formed via a dielectric film on the reverse-conducting N+ diffusion layer and the P-type semiconductor substrate. The N+ diffusion layer is connected to the N-type well of diode, and the diode regulates the current.

### BACKGROUND OF THE INVENTION

1. Field of the Invention

The present invention relates to a semiconductor memory device for breaking down the dielectric of the dielectric film and, containing an antifuse for causing an electrical short between the terminal and the substrate to perform writing.

2. Description of Related Art

In an increasing number of cases in recent years, logic LSI require ultra-small capacity non-volatile memories ranging from several hundred bits to several thousand kilobits in order to store color parameters for LCD (liquid crystal display) drivers and temperature compensation parameters for clock control in the LSI (large scale integration) devices. Unlike the internal flash memories in dedicated microcomputers, these type of ultra-small capacity non-volatile memories can be manufactured without increasing the number of manufacturing steps in the standard CMOS process, even though their memory cell size is somewhat larger. One example of these ultra-small capacity non-volatile memories is semiconductor storage devices containing an antifuse that writes by breaking down the dielectric of the dielectric film to cause an electrical short between the electrode and substrate (See for example, patent documents 1, 2.)

JP-A No. 504434/2005 discloses technology for a non-volatile memory cell 100 including a select transistor 121 serially connected to a data storage element 125 serving as the antifuse. This data storage element 125 includes a conductive structure 101, an ultra-thin dielectric film 112 below the conductive structure 101 for physically storing data, a doped semiconductor region 106 below both the ultra-thin dielectric film 112 and the conductive structure 101. The select transistor 121 includes a gate R2 capable of control for specifying an address for the memory cell 100 and, applies a voltage across the conductive structure 101 and doped semiconductor region 108 to break down the ultra-thin dielectric film 112 and write on the memory cell 100 (See FIG. 9.)

JP-A No. 235836/2005 discloses technology for a semiconductor storage device utilize as an antifuse and including a semiconductor substrate 201, a well 202 formed on this semiconductor substrate 201, a MOS transistor 230 serving as the select transistor formed within this well 202, a diffusion layer 241 existing within the well 202 and having the same conductivity as the source 232 or the drain 231 of the MOS transistor 230, and a MOS capacitor 240 serving as the antifuse possessing a sequentially laminated structure of a dielectric film 242, 243, and a conductive film 244 as this diffusion layer 241. The thickness of the dielectric film 243 in the center of the MOS capacitor 240 is thinner than the thickness of the dielectric film 242 on the periphery. Writing is performed by applying a voltage equal to or higher than the breakdown voltage to the thin dielectric film 243 of the capacitor 240 to break down the dielectric of the dielectric film 243 (See FIG. 10).

### SUMMARY

In semiconductor storage devices containing a select transistor and an antifuse, the select transistor is usually formed without adding an additional step (process) to the CMOS process. Therefore as the process becomes more complex, the doping level in the well (p well) forming the select transistor becomes more concentrated, and the depth of the source/drain diffusion layer (n+ diffusion layer) becomes shallower. The higher doping concentration and shallow diffusion layer cause a lower breakdown (withstand) voltage in the drain diffusion layer, and the voltage that can be applied to the antifuse diffusion layer drops so that when the process for the semiconductor structure in the patent documents 1 and 2 become more complicated, the junction voltage across the well and diffusion layer might become incapable of rising to a voltage sufficiently higher than the dielectric film breakdown voltage of the antifuse. This situation creates the problem that causing a reliable breakdown in the dielectric film of the antifuse becomes impossible.

This invention therefore has the main object of achieving reliable breakdown of the dielectric during writing on the dielectric film of the antifuse even when the process has become complicated.

A first aspect of this invention is characterized in including: a dielectric film formed on a substrate and a portion of that dielectric film region is broken down during writing, an electrode formed on that dielectric film, an antifuse made up of a first diffusion region formed directly below a portion of that region, and a well of the same conduction type as the first diffusion region, formed so as to cover a portion or the entire region where the first diffusion region contacts the substrate.

A semiconductor storage device of a second aspect of this invention including: a dielectric film formed on a substrate and a portion of that dielectric film region is broken down during writing, an electrode formed on that dielectric film, an antifuse made up of a first diffusion region formed directly below that region, a well of the same conduction type as the first diffusion region, formed so as to cover a portion or the entire region where the first diffusion region contacts the substrate, and a diode formed from a second diffusion layer of a reverse conducting type the above described well and a first diffusion region formed in the interior of that well; and the memory cell is made up of the above described antifuse and diode; and in the memory cell, word lines are formed to the antifuse electrode and digit lines are formed to the input terminal of the diode; and characterized in that during writing of the antifuse, the control circuits for the semiconductor devices containing an array of multiple memory cells where a first voltage, and a second voltage higher than the first voltage are applied respectively to the word lines and to the digit lines of the antifuse to be written on, and when not writing, maintain the word lines and digit lines of the antifuse not to be written on are set to the same voltage potential, or the voltage potential of the word lines and digit lines are set respectively at the second voltage, and the first voltage.

A control method for a third aspect of this invention, for forming memory cells from antifuses and diodes connected to those antifuses, with memory cells including word lines formed at the antifuse electrode, and digit lines formed at input terminals of the diodes and, selectively reading and writing on the multiple memory cells arrayed with those word lines and digit lines; and

characterized in applying a first voltage and a second voltage higher than the first voltage so as to form a voltage differential to induce breakdown of the antifuse on the digit line and the word line of the antifuse for writing and, and to set the word line and digit line of the antifuse not for writing to the same voltage potential, or to set the word line and digit line respectively to the second voltage and the first voltage, and

to apply a third voltage, and a fourth voltage higher than the third voltage respectively to the word line and digit line of the antifuse for reading and, set the word line and digit line of an antifuse not for reading to the same voltage potential or set the word line and digit line voltage potential respectively to a fifth voltage higher than the fourth voltage and less than the fourth voltage.

This invention can apply a voltage sufficient to induce the dielectric breakdown required for writing, even when the source/drain diffusion layer withstand voltage of the select transistor becomes low due to a complicated process and therefore the write operation can be reliably performed.

### BRIEF DESCRIPTION OF THE DRAWINGS

FIG. 1A shows the structure of the structure of the semiconductor storage device of the first embodiment of this invention;

FIG. 1B is a diagram of the equivalent circuit;

FIG. 2 is a circuit diagram showing the write operation in the semiconductor storage device of the first embodiment of this invention;

FIG. 3 is a circuit diagram showing the read operation in the semiconductor storage device of the first embodiment of this invention;

FIG. 4 is a fragmentary cross sectional view showing the structure of the semiconductor storage device of the second embodiment of this invention;

FIG. 5A is a fragmentary cross sectional view showing the structure of the semiconductor storage device of the third embodiment of this invention;

FIG. 5B is a diagram of the equivalent circuit;

FIG. 6 is a circuit diagram showing the write operation in the semiconductor storage device of the third embodiment of this invention;

FIG. 7 is a circuit diagram showing the read operation in the semiconductor storage device of the third embodiment of this invention;

FIG. 8 is a drawing showing a section common to the first, second, and third embodiments;

FIG. 9 is a fragmentary cross sectional view showing the structure of the semiconductor storage device of a first example of the related art; and

FIG. 10 is a fragmentary cross sectional view showing the structure of the semiconductor storage device of a second example of the related art.

### DETAILED DESCRIPTION OF THE INVENTION

### First Embodiment

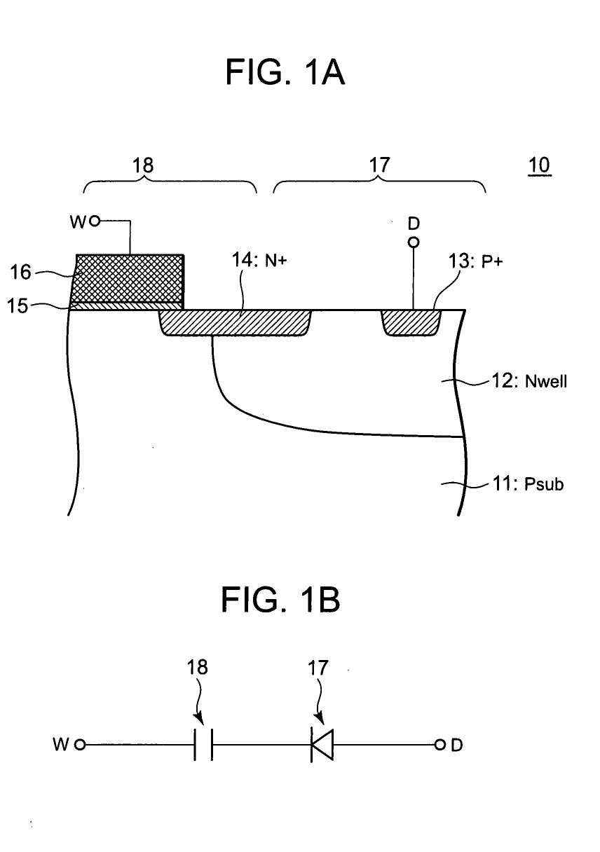

The first embodiment of the semiconductor storage device this invention is described next while referring to the drawings. FIG. 1A is a fragmentary cross sectional view showing the structure of the semiconductor storage device of the first embodiment of this invention. FIG. 1B is a diagram of the equivalent circuit.

In a semiconductor storage device 10 in FIG. 1A, an N-type well 12 is formed on a specified region of a P-type semiconductor substrate 11. The N-type well 12 conducts in the reverse of the P-type semiconductor substrate 11. A diode 17 serving as the current regulator is formed within the N-type well 12 region. The diode 17 is a diode with a pn junction for the N-type well 12 and a P+ diffusion layer 13. The P+ diffusion layer 13 is the same conducting type as the P-type semiconductor substrate 11 and is electrically connected to a digit line D. An antifuse 18 serving as the memory node is formed on the P-type semiconductor substrate 11. The antifuse 18 is an element that writes by breaking down the dielectric of the dielectric film 15, to short the N+ diffusion layer 14 and the electrode 16. An electrode 16 is laminated on the P-type semiconductor substrate 11 via the dielectric film 15, and an N+ diffusion layer 14 is formed on a section of the P-type semiconductor substrate 11 surface directly below the electrode 16. The electrode 16 is electrically connected to a word line W. The N+ diffusion layer 14 is formed on the P-type semiconductor substrate 11 in the region between the antifuse 18 and the diode 17. The N+ diffusion layer 14 is a type that conducts in the reverse of the P-type semiconductor substrate 11. The N+ diffusion layer 14 is consecutively formed so as to connect from a section on the surface of the P-type semiconductor substrate 11 directly below the electrode 16, to a section of the surface on the N-type well 12. In the semiconductor storage device 10 of FIG. 1A, the diode 17 and the antifuse 18 are serially connected as shown in the circuit in FIG. 1B.

The semiconductor storage device 10 can be produced in parallel with the normal CMOS process. When forming a well for example, the N-type well 12 can be formed on the P-type semiconductor substrate 11; and when forming the gate dielectric film and the gate electrode, the dielectric film 15 and the electrode 16 can be formed; and when forming the source/drain diffusion layer for the pMOS transistor and the nMOS transistor, a P+ diffusion layer 13 and an N+ diffusion layer 14 can be produced.

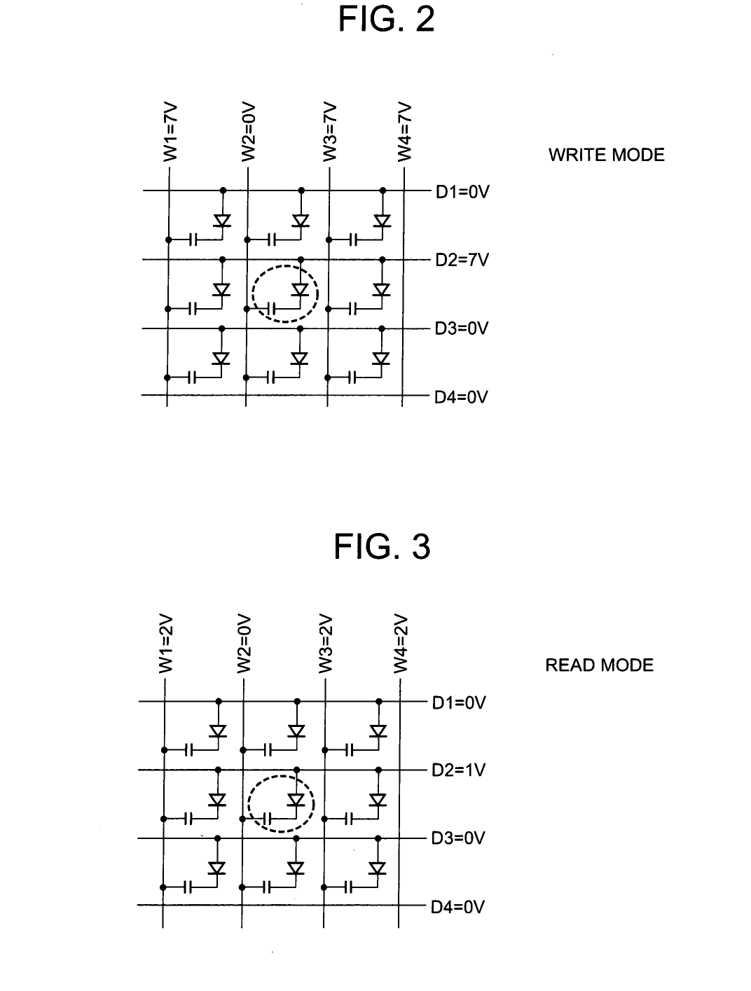

The operation of the semiconductor storage device of the first embodiment of this invention is described next while referring to the drawings. FIG. 2 is a circuit diagram showing the write operation in the semiconductor storage device of the first embodiment of this invention. FIG. 3 is a circuit diagram showing the read operation in the semiconductor storage device of the first embodiment of this invention.

In the write operation as shown in FIG. 1, the select transistor sets the word line W (corresponding to W2 in FIG. 2) connected to the terminal 16 of the antifuse 18 serving as the selected memory node to GND voltage (0 volts), and applies a positive high voltage (for example, 7 volts) to the digit line (corresponding to D2 in FIG. 2) connected to the P+ diffusion layer 13 of diode 17 serving as the current regulator in order to apply a breakdown voltage to the N+ diffusion layer 14 via the N type well 12. The diode 17 performs current regulation so by applying a positive voltage in the conduction direction of P+ diffusion layer 13 during write operation, a sufficiently high voltage can be applied to breakdown the dielectric (insulation) of the dielectric film 15, up to the junction withstand voltage between the N well 12 and the P-type semiconductor substrate 11 or the withstand voltage of the N+ diffusion layer 14. Applying this protective voltage to the electrodes of non-selected antifuses prevents breaking down the dielectric of the dielectric film 15. Referring for example to FIG. 2, when writing on a memory cell enclosed by the thick dotted line, applying a protective voltage of 7 volts for example to the word lines W1, W3, W4 and setting the digit lines D1, D3, D4 to GND voltage (0 volts), protects the dielectric films of memory cells other than those enclosed by the thick dotted line from breakdown.

In the read operation in FIG. 1, the select transistor applies a positive low voltage (for example 1 volt) to the digit line D (corresponding to D2 in FIG. 3) connected to the P+ diffusion layer 13 of the diode 17 serving as the current regulator, and sets the word line W (connected to W2 in FIG. 3) connected to the electrode 16 of the antifuse 18 serving as the selected memory node to GND voltage (0 volts) Data is then read by the voltage detector unit (not shown in drawing) connected to the word line W, detecting a positive low voltage or 0 volts. At this time, a positive low voltage is applied to the non-select antifuse electrode and the P+ diffusion layer is set to GND voltage. Referring for example to FIG. 3, when reading the memory cells enclosed by the thick dotted line, the select transistor applies a positive low voltage to the word lines W1, W3, W4 (for example 2 volts), and sets the digit lines D1, D3, D4 to GND voltage (0 volts) to prevent reading memory cells that are not enclosed by the thick dotted line.

In the first embodiment, the antifuse 18 for breaking down the dielectric of the dielectric film 15 is capable of high-speed, high-reliability writing by applying a voltage sufficient to induce breakdown of the dielectric required for writing, even if the withstand voltage of the source/drain diffusion layer of the select transistor becomes low due to a complicated process, etc.

### Second Embodiment

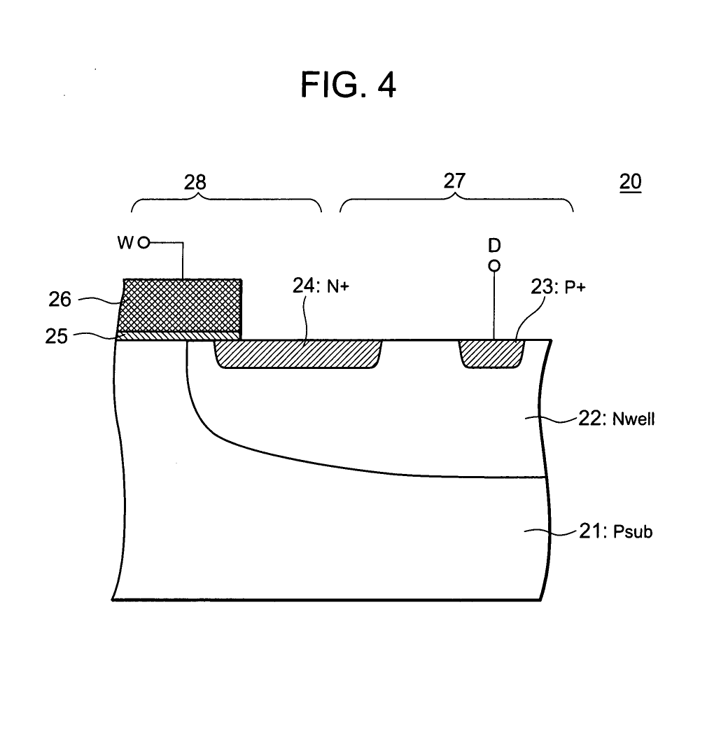

The semiconductor storage device for the second embodiment of this invention is described next while referring to the drawings. FIG. 4 is a fragmentary cross sectional view showing the structure of the semiconductor storage device of the second embodiment of this invention. The equivalent circuit is completely identical to the circuit shown in FIG. 1B.

The semiconductor storage device 20 in FIG. 4 includes an N-type well 22 formed on a specified region of a P type semiconductor substrate 21. The N-type well 22 is the conducts in the reverse of the P type semiconductor substrate 21. An N+ diffusion layer 24 is formed within the N-type well 22 region, as well as a diode 27 serving as the current regulator. The diode 27 is a pn junction diode for the N-type well 22 and P+ diffusion layer 23. The P+ diffusion layer 23 is the same conducting type as the P type semiconductor substrate 21 and is electrically connected to the digit line D. An antifuse 28 serving as the memory node is formed on a portion of the regions on the P type semiconductor substrate 21 and the N-type well 22 and P+ diffusion layer 23. The antifuse 28 is an element for breaking down the dielectric film 25 and, to write by causing a short between the N+ diffusion layer 24 and the electrode 26. The electrode 26 is laminated via the dielectric film 25 on a portion of the regions of the P type semiconductor substrate 21 and the N-type well 22 and the N+ diffusion layer 24. An N-type well 22 is formed on a portion of the surface of the P type semiconductor substrate 21 directly below the electrode 26. The P+ diffusion layer 23 is formed on a portion of the surface of the N-type well 22 directly below the electrode 26. The electrode 26 is electrically connected to the word line W. The diode 27 and the antifuse 28 are formed adjacent to one another. The semiconductor storage device 20 in FIG. 4 is a circuit with the antifuse 28 and the diode 27 serially connected as shown in FIG. 1B.

The semiconductor storage device 20 can be produced in parallel with the normal CMOS process. When forming a well for example, the N-type well 22 can be formed on the P-type semiconductor substrate 21; and when forming the gate dielectric film and the gate electrode, the dielectric film 25 and the electrode 26 can be formed; and when forming the source/drain diffusion layer for the nMOS transistor, a P+ diffusion layer 23 can be produced. Moreover, the semiconductor storage device 20 circuit is equivalent to the circuit of the semiconductor device (10 in FIG. 1) of the first embodiment so that the operation of the semiconductor storage device 20 is identical to the operation of the semiconductor storage device (10 in FIG. 1) of the first embodiment.

In the second embodiment, the antifuse 28 for breaking down the dielectric of the dielectric film 25 is capable of high-speed, high-reliability writing by applying a voltage sufficient to induce breakdown of the dielectric required for writing, even if the withstand voltage of the source/drain diffusion layer of the select transistor becomes low due to a complicated process, etc. The withstand (voltage) capacity of the N+ diffusion layer 24 is also improved because it is enclosed completely by the N well 22. Therefore, a breakdown can be reliably induced in the dielectric and the reliability of the antifuse writing operation improved.

### Third Embodiment

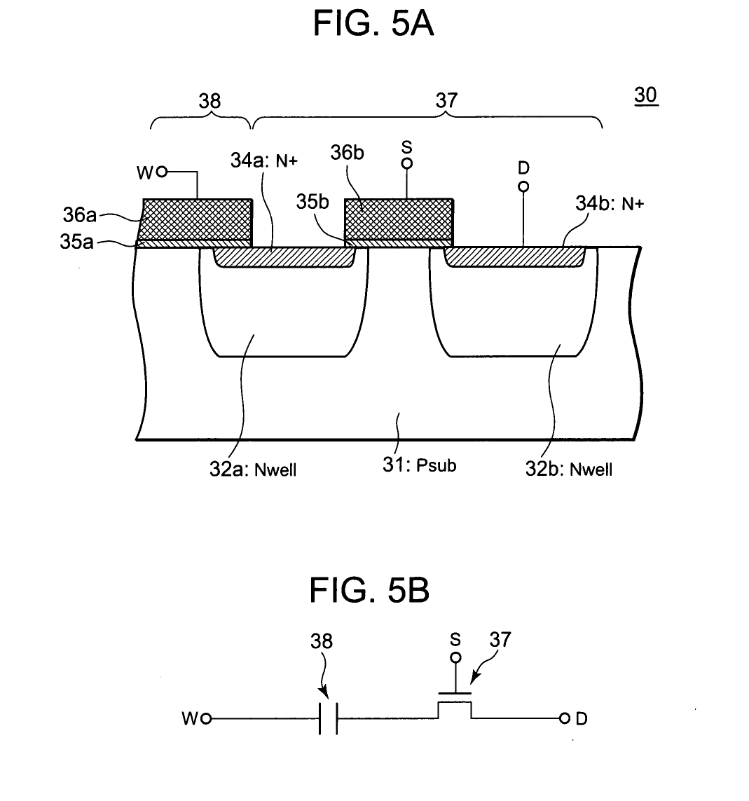

The semiconductor storage device for the third embodiment of this invention is described next while referring to the drawings. FIG. 5A is a fragmentary cross sectional view showing the structure of the semiconductor storage device of the third embodiment of this invention. FIG. 5B is a diagram of the equivalent circuit.

A semiconductor storage device 30 in FIG. 5A includes a select transistor serving as the current regulator. In the select transistor 37, the N-type wells 32a, 32b are formed on both side of a P type semiconductor substrate 31 serving as the channel; N+ diffusion layers 34a, 34b serving respectively as the source/drain are formed within N-type well 32a, 32b regions; and a gate electrode 36b is formed via the gate dielectric film 35b on the P type semiconductor substrate 31 serving as the channel. The N-type wells 32a, 32b and the N+ diffusion layers 34a, 34b conduct in the reverse (direction) of the P type semiconductor substrate 31. The antifuse 38 and the non-common N+ diffusion layer 34b are electrically connected to the digit line D. The gate electrode 36b is electrically connected to the select line S. The semiconductor storage device 30 includes an antifuse 38 serving as the memory node in the region adjoining the select transistor 37. The antifuse 38 is an element for breaking down the insulation (dielectric) of the dielectric film 35 to cause a short between the N-type wells 32a through N+ diffusion layers 34a and the electrode 36a. The antifuse 38 is formed on a portion of the P type semiconductor substrate 31, the N-type well 32a and the N+ diffusion layers 34a. The electrode 36a is laminated via the dielectric film 35a. The N-type well 32a is formed on a portion of the surface of the P type semiconductor substrate 31 directly below the electrode 36a. The N+ diffusion layer 34a is formed on a portion of the surface of the N-type well 32a directly below the electrode 36a. The electrode 36a is electrically connected to the word line W. The semiconductor storage device 30 in FIG. 5A is a circuit where the select transistor 37 and the antifuse 38 are serially connected as shown in FIG. 5B.

The semiconductor storage device 30 can be produced in parallel with the normal CMOS process. The N type wells 32a, 32b for example can be formed on the P type semiconductor substrate 31 when forming the wells; and the dielectric film 35a, electrode 36a, gate dielectric film 35b and the gate electrode 36b can be formed when forming the gate dielectric film and the gate electrode; and the N+ diffusion layers 34a, 34b can be formed when forming the source/drain diffusion layers for the pMOS transistor.

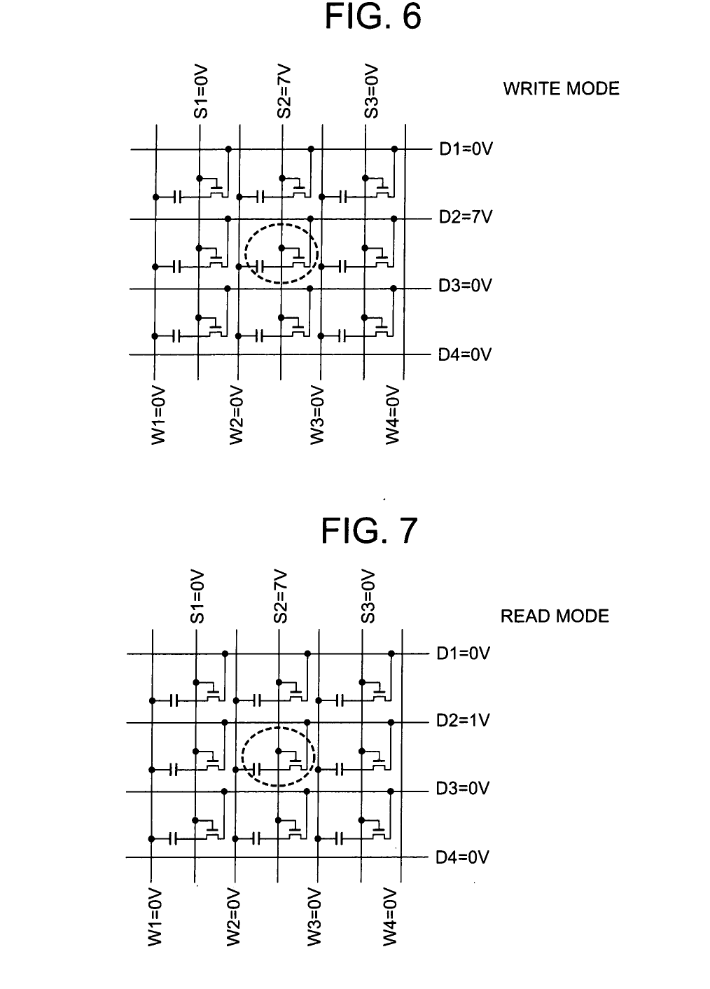

The operation of the semiconductor storage device of the third embodiment of this invention is described next while referring to the drawings. FIG. 6 is a circuit diagram showing the write operation in the semiconductor storage device of the third embodiment of this invention. FIG. 7 is a circuit diagram showing the read operation in the semiconductor storage device of the third embodiment of this invention.

In the write operation in FIG. 5, the select transistor applies a positive high voltage (for example 7 volts) to the select line S (corresponding to S2 in FIG. 6) connected to the gate electrode 36b of the select transistor 37 serving as the selected current controller; sets the word line W (corresponding to W2 in FIG. 6) connected to the electrode 36a of the antifuse 38 serving as the selected memory node to GND voltage (0 volts); and by setting the digit line D (corresponding to D2 in FIG. 6) connected to the N+ diffusion layer 34b of the select transistor 37 serving as the selected current regulator to a positive high voltage (for example, 7 volts); applies a breakdown voltage to the N type wells 32a through N+ diffusion layer 34a. The select transistor 37 performs current regulation and by applying a positive voltage to the gate electrode 36b during the write operation can apply a sufficiently high voltage (up to the withstand voltage of N+ diffusion layer 34a) to break down the dielectric film 35a. At this time, the gate electrode of the select transistor that was not selected is set to GND voltage (0 volts), and the N+ diffusion layer of the select transistor that was not selected is set GND voltage (0 volts), and the electrode of the non-selected antifuse is set to GND voltage (0 volts). When writing on the memory cell enclosed by the thick dotted line shown for example in FIG. 6, the select lines S1, S3 are set to GND voltage (0 volts); the word lines W1, W3, W4 are set to GND voltage (0 volts), and the digit lines D1, D3, D4 are set to GND voltage (0 volts) so that no writing is performed on memory cells not enclosed by the thick dotted line.

In the read operation in FIG. 5, the select transistor applies a positive high voltage (for example, 7 volts) to the select line S (corresponding to S2 in FIG. 7) connected to the gate electrode 36b of the select transistor 37 serving as the selected current regulator, sets the word line W (corresponding to W2 in FIG. 7) connected to the electrode 36a of the antifuse serving as the selected memory node is set to GND voltage (0 volts), and applies a positive low voltage (for example, 1 volt) to the digit line D (corresponding to D2 in FIG. 7) connected to the N+ diffusion layer 34b of the select transistor 37 serving as the selected current regulator. The voltage detector unit (not shown in drawing) connected to the word line W reads the data by detecting a positive low voltage or zero volts. At this time, the select transistor sets the gate electrode of the non-selected select transistor to GND voltage (0 volts) and the N+ diffusion layer of the non-selected select transistor to GND voltage (0 volts). When reading the memory cell enclosed by the thick dotted line as shown in FIG. 7, setting the select lines S1, S3 to GND voltage (0 volts), and setting the word lines W1, W3, W4 to GND voltage (0 volts); and setting the digit lines D1, D3, D4 to GND voltage (0 volts) prevent reading of memory cells other than the memory cell enclosed by the thick dotted line.

In the third embodiment, the antifuse 38 for breaking down the dielectric of the dielectric film 35a is capable of high-speed, high-reliability writing by applying a voltage sufficient to induce breakdown of the dielectric required for writing, even if the withstand voltage of the source/drain diffusion layer of the select transistor becomes low due to a complicated process, etc. This embodiment occupies a larger surface area than the first and second embodiments. However, this embodiment can prove effective in cases where there are a small number of components or there are comparatively few restrictions on component placement. This embodiment is effective since that the method for controlling select/non-select of the antifuse array (memory cell array) is extremely simple compared to the first and second embodiments, and the load on the those control circuit arrays is light.

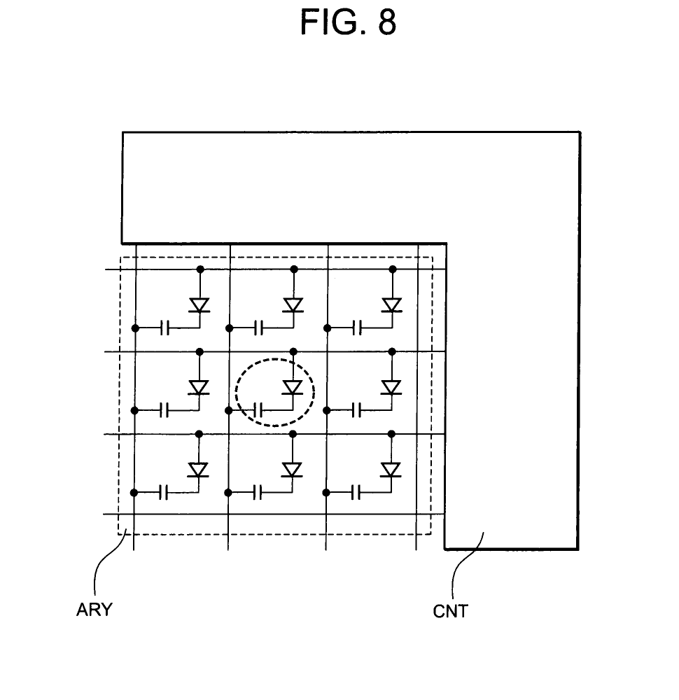

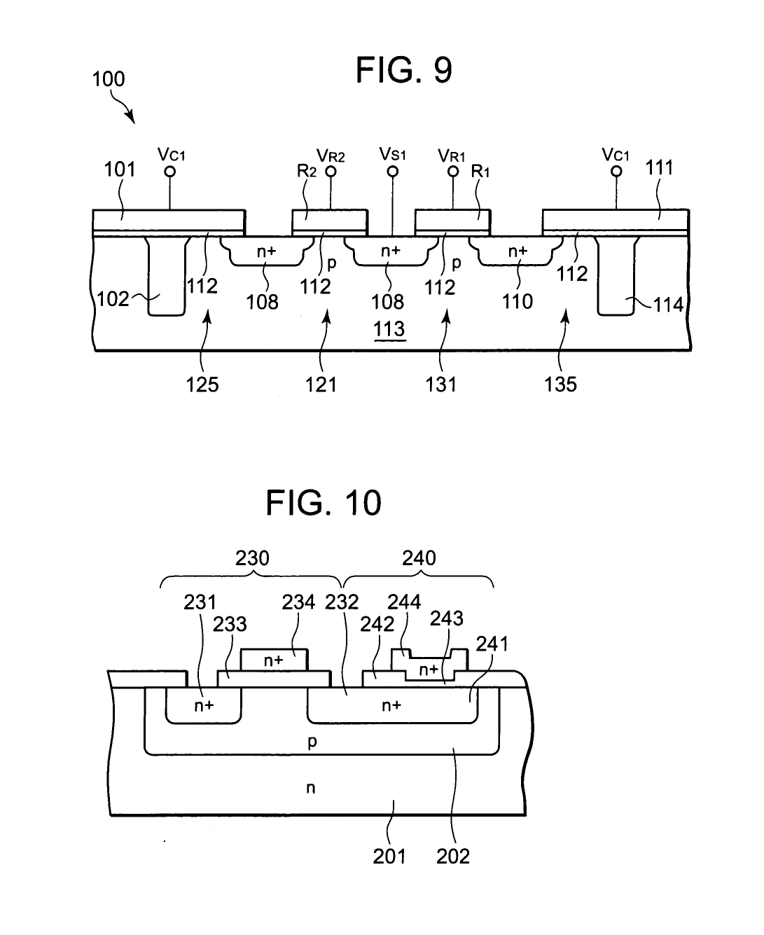

Here, an array of antifuses (memory cells) common to the first, second, and third embodiments is shown in the diagram in FIG. 8 as a supplement. In the structure in the figure, the antiphase array (memory cell array) is set as ARY and the structure includes a control circuit CNT to control this ARY.

What is claimed is:

1. A semiconductor storage device having an antifuse, the antifuse comprising:
a dielectric film formed on a substrate;
an electrode formed on the dielectric film;
a first diffusion region formed below the dielectric film; and
a well having the same conductivity type as the first diffusion region and formed to cover at least a part of the first diffusion region.

2. The semiconductor storage device according to claim 1, further comprising a switching element for controlling the select/non-select status of the antifuse.

3. The semiconductor storage device according to claim 2, wherein the switching element is a transistor with a high withstand voltage.

4. The semiconductor storage device according to claim 3, wherein the diffusion region on the side connecting to the antifuse for the high withstand voltage transistor is jointly used as the first diffusion region in the antifuse.

5. The semiconductor storage device according to claim 2, wherein the switching element is a diode.

6. The semiconductor storage device according to claim 5, wherein the diode is formed with the well and a second diffusion region having a reverse conducting type as the first diffusion region, the second diffusion region being formed within the well.

7. The semiconductor storage device according to claim 1, wherein the well formed to cover all of the first diffusion region.

8. A semiconductor storage device, comprising:
an antifuse which comprising;
a dielectric film formed on the substrate,
an electrode formed on the dielectric film,
a first diffusion region formed below the dielectric film; and
a well having a same conducting type as the first diffusion region formed to cover at least a part of the first diffusion region;
a diode formed with the well and a second diffusion region having a reverse conductivity type as that of the first diffusion region, the second diffusion region being formed within the well,
wherein a memory cell includes the antifuse and the diode,
wherein in the memory cell, the word lines are formed at the antifuse electrode and digit lines are formed at the input terminal of the diode, and
wherein, in the control circuits for the semiconductor devices including an array of multiple memory cells,
during writing of the antifuse, a first voltage, and a second voltage higher than the first voltage are applied respectively to the word lines and to the digit lines of the antifuse for writing, and
the word lines and digit lines of the antifuse not to be written on are set to the same voltage potential, or the voltage potential of the word lines and digit lines are set respectively at the second voltage, and the first voltage.

9. The semiconductor storage device according to claim 8, wherein, when reading the antifuse, the control circuits apply a third voltage, and a fourth voltage larger than the third voltage respectively to the word line and the digit line, and
the control circuits set the word lines and digit lines of antifuses not for reading, to the same voltage potential or respectively to a fifth voltage higher than the fourth voltage and a less than the fourth voltage.

10. A semiconductor storage device, comprising:
a substrate of a first conductive type;
a first region of a second conductive type selectively formed in the substrate;
a second region selectively formed in the substrate apart from the first region;
a third region of a second conductive type selectively formed in a portion of the substrate between the first portion and the second portion;
a dielectric film formed on apart of the first region;
an electrode formed on the dielectric film;
wherein an antifuse is comprised of the part of the first region, the dielectric film, and the electrode.

11. The semiconductor storage device according to claim 10, wherein the second region is the first conductive type.

12. The semiconductor storage device according to claim 10, wherein the second region is the second conductive type.

13. The semiconductor storage device according to claim 10, wherein the third region covering the first region to provide a voltage enough to breakdown the dielectric film of the antifuse from the second region to the part of the first region.
